(19) United States
(12) Patent Application Publication
(10) Pub. No.: US 2017/0215297 A1
(43) Pub. Date: Jul. 27, 2017

(54) MODULE WITH LATERALLY TRANSLATABLE COMPONENT PLATFORM

(71) Applicant: Intel Corporation, Santa Clara, CA (US)

(72) Inventors: Gene F. Young, Lexington, SC (US); Gregory M. Kuzmanich, Portland, OR (US)

(21) Appl. No.: 15/006,684

(22) Filed: Jan. 26, 2016

(51) Int. Cl. H05K 7/14

(52) U.S. Cl. CPC H05K 7/1489; H05K 7/1488

(57) ABSTRACT

Devices and methods include a component module configured for installation into a server. The component module includes a frame configured for installation in an installation direction. A component platform is movably coupled to the frame and movable between interfaced and decoupled positions. In one example, a component actuator arm extends between first and second actuator ends. A hinge rotatably couples the component actuator arm to the frame and is remote from the first actuator end, and the component actuator arm is rotatably coupled to the component platform at a joint, wherein the component actuator arm is movable between a decoupled configuration and an interfaced configuration. In the decoupled configuration, the component platform is in the decoupled position and recessed relative to the interfaced position. In the interfaced configuration, the component actuator arm is rotated relative to the decoupled configuration, and the component platform is laterally moved into the interfaced position relative to the installation direction by the component actuator arm.

### TECHNICAL FIELD

This document pertains generally, but not by way of limitation, to electronic modules, such as electronic component modules for servers.

### BACKGROUND

Electronic devices, such as electronic computer devices, can include a PCI Express card, memory, graphics processor, power supply, or hard drive. In some examples, the electronic device can be connected to a server through a computer component, such as a motherboard, a PCI, or backplane connector. The electronic devices can be attached to one or more of the computer components and/or a server chassis. For instance, the computer component (e.g., motherboard) can be fastened to the server chassis and a cover can be coupled to the server chassis to protect the computer components and electronic devices within the server. In some examples, the electronic device can be removed from the server for repair, replacement, or other purposes. The server can be powered down and the cover of the server can be removed to expose the one or more electronic devices for removal or to provide access to install an electronic device. When the cover is removed, the computer components and electronic devices can be vulnerable to damage or electrical shorting. Accordingly, the server can be powered down when the cover is removed to mitigate damage to the server and/or the electronics devices and computer components therein.

In some examples, the server can be mounted on a server rack. The server rack can include a plurality of servers stacked vertically on the server rack. The server racks can include slidable server mounts to permit each server to be slid out independently from other adjacent servers, for instance, so the cover of the server can be removed for installing, removing, or replacing the electronic device. However, the addition of slidable server mounts can add to the cost and complexity of the server racks.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a perspective view of an exemplary server including a component module bay and a component module partially installed within the component module bay.

FIG. 2 shows a server rack including a plurality of servers, the component module bay of each server being accessible along an installation direction of the component module according to an example.

FIG. 3 is a perspective view of the component module according to an example.

FIG. 4A shows an example of the component actuator arm in the decoupled configuration and the component platform in the decoupled position.

FIG. 4B shows an example of the component actuator arm in the interfaced configuration and the component platform in the interfaced position.

FIG. 5 is a perspective view of an example of the component module including a component mounted to a component platform of the component module.

FIG. 6A shows an example of the component in the decoupled position.

FIG. 6B shows an example of the component in the interfaced position.

FIG. 7 is a block diagram of an exemplary method of making a component module according to an example.

FIG. 8 is a system diagram of an electronics device including the component module according to an example.

### DESCRIPTION OF EMBODIMENTS

A server and a component module are described herein, such as a component module that is installable within a component module bay of the server. The component module can include a component. The component can include a component contact interface having an engagement axis oriented laterally from an installation direction of the component module. The component contact interface is engageable with a server contact interface. The server contact interface also includes an engagement axis oriented laterally from the installation direction of the component module and can be aligned with the component contact interface. The component module can be installable while the server is in operation (e.g., powered on) and statically mounted within a server rack. For instance, the component module can be installed within the component module bay of the server and the component contact interface can be engaged with the server contact interface while the server remains in operation within the server rack.

The following description and drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

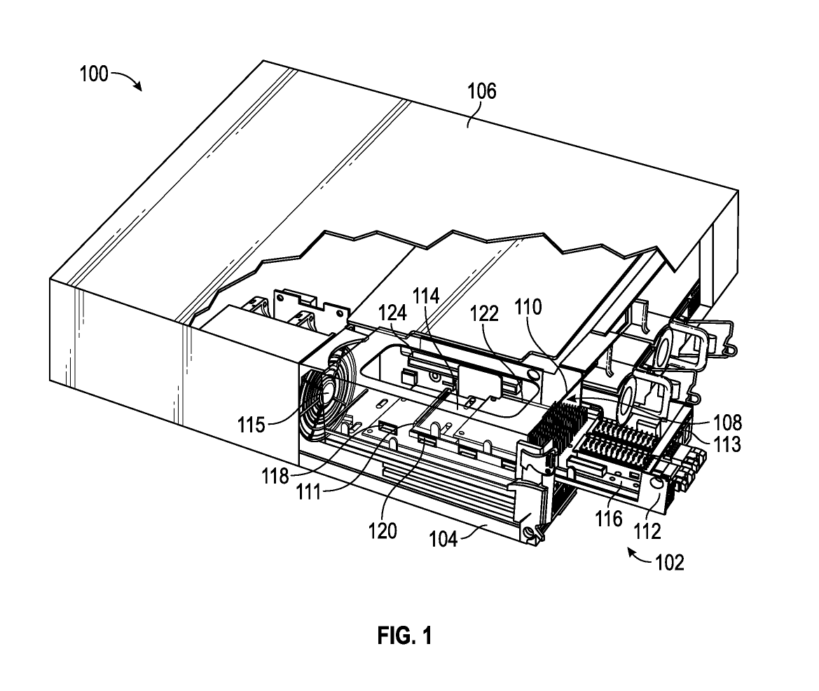

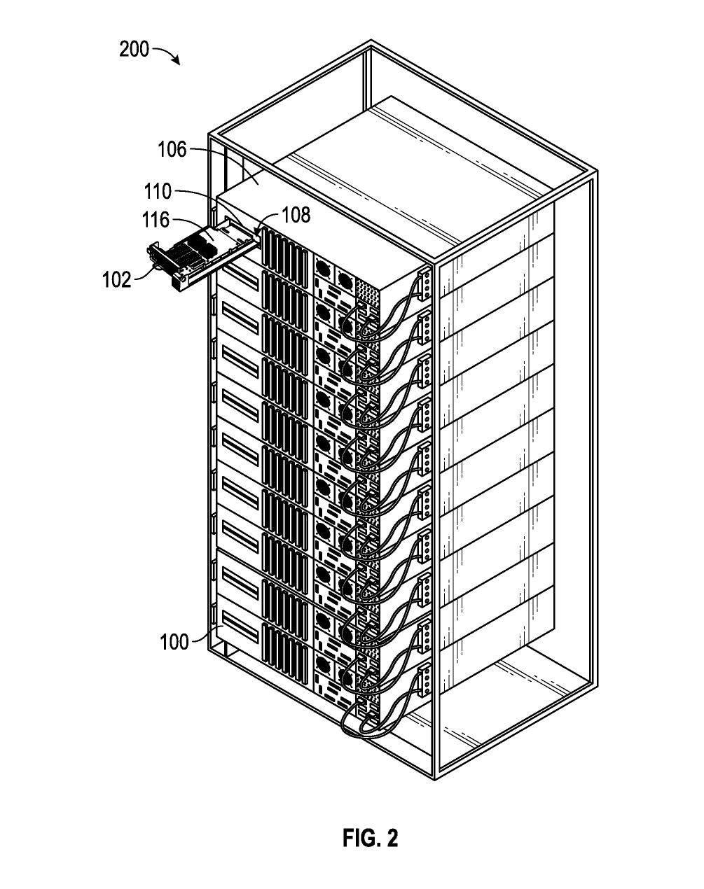

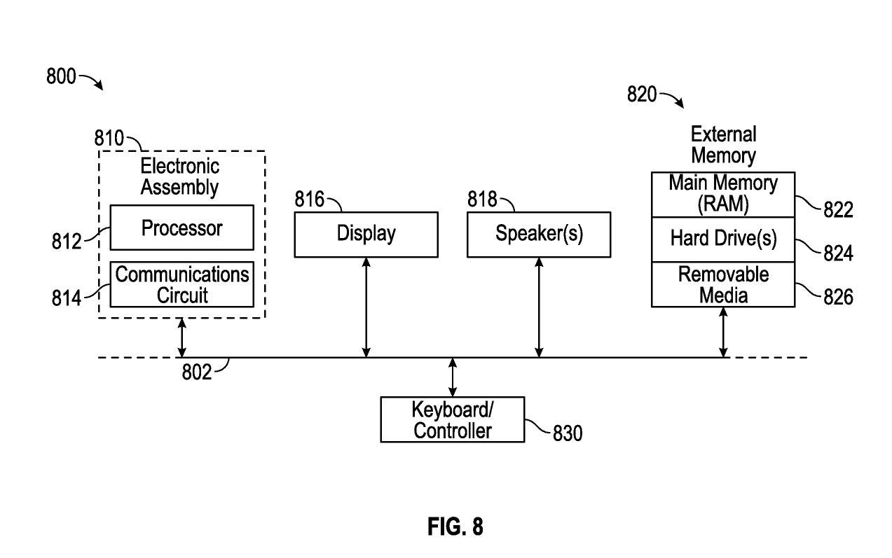

FIG. 1 shows an exemplary server 100 including a component module 102. The server 100 can include a chassis 104, cover 106, and a component module bay 108 for the installation of the component module 102 along an installation direction. The chassis 104 can support various server components including, but not limited to, a motherboard, power supply, hard drive, memory module, or the like. For instance, the chassis 104 can include a metal or polymer structure having supports for coupling server components to the chassis 104. The cover 106 (shown in a removed state in FIG. 1) can be removably attached to the chassis 104 to protect the server components from debris or damage and to provide access to the server components. For instance, the cover 106 can snap or slide over the chassis 104 in a removably attachable manner. The cover 106 can be constructed from a material including, but not limited to, a metal or polymer. The component module bay 108 can be located inside the server 100. For instance, the cover 106 can enclose or partially enclose the component module bay 108. An opening 110 can be located at an external end of the component module bay 108 for the installation of the component module 102. The opening 110 can be located on the chassis 104, the cover 106, or both. In one example, a fan 115 can be located at an internal end of the component module bay 108 to direct airflow through the component module bay 108. The chassis 104 can include mounts for supporting the component module 102 within the component module bay 108. Further examples of the server 100 are discussed later herein and shown in FIGS. 2 and 8.

The component module 102 can include a frame 112, a component platform 114, and a component 116 coupled to the component platform 114. The frame 112 can be movably coupled with the chassis 104 of the server 100. For instance, the component module 102 can be slid into the component module bay 108 along an installation direction. In other words, the component module 102 can be installed in the component module bay 108. The frame 112 can include an internally facing end 111 and an externally facing end 113. Where the component module 102 is installed, the externally facing end 113 is located toward an external end of the component module bay 108 and the internally facing end 111 is located toward an internal end of the component module bay 108. In one example, the component module 102 can be coupled to the chassis 104 with fasteners including, but not limited to, screws, clips, snaps, magnets, or other type of fastener. In the example of FIG. 1, the chassis 104 can include mounts 118. The mounts 118 can include one or more flanges. The frame 112 can include a rail 120 configured to be supported by the one or more flanges of the mount 118. For instance, the rail 120 can be supported between a top and bottom flange and can be slidable on the one or more mounts 118 along the installation direction. In some examples, the mount 118 can be included on the frame 112 and the rail 120 can be included on the chassis 104 and vice-versa. In other examples, the component module 102 can be movably coupled with the server 100 by other couplings including, but not limited to, sliders, rollers, brackets, or the like.

The component 116 can include a component contact interface 122. The component contact interface 122 can include an engagement axis that is oriented in a lateral or substantially lateral direction (e.g., transverse or within five degrees of a lateral direction) with respect to the installation direction of the component module 102. The server 100 can include a server contact interface 124. The server contact interface 124 can be located on a server component, such as a motherboard or a backplane. For instance, the server contact interface 124 can include an engagement axis that is oriented in a lateral direction from the installation direction of the component module 102. The component contact interface 122 and the server contact interface 124 can be aligned for engagement (engageable) with one another.

As previously stated, the component 116 can be coupled to the component platform 114. The component platform 114 can be movable with respect to the frame 112. For instance, the component platform 114 can move between a decoupled position and an interfaced configuration along a lateral direction with respect to the installation direction. Accordingly, the component contact interface 122 can be engaged with the server contact interface 124 along the lateral direction in response to the movement of the component platform 114. As a result, the component 116 can be installed or replaced when the server 100 is in operation and/or powered on, according to one or more examples. Stated another way, the component 116 can be hot swapped when the cover 106 is attached to the chassis 104 and encloses the server components. Because the component 116 can be installed with the cover 106 in place, the need for costly and space consuming baffles is reduced. For instance, baffles may not be needed for protecting the server components exposed when the cover 106 is removed. In one example, the internally facing end 111 of the frame 112 can be located adjacently to the fan 115. As a result of the lateral position of the server contact interface 124, the fan 115 can generate airflow around the component 116 unobstructed by the server contact interface 124.

FIG. 2 is an exemplary server rack 200 including a plurality of servers 100. The one or more servers 100 can be located adjacently to one another. For instance, the server 100 can be located above, below, to the right, or to the left of another server 100 as shown in FIG. 2. In one example, the server 100 can include a front and back side. For instance, the front side can include a name plate, indicator lights, controls, or the like. The back side of the server 100 can include electrical connectors, ports, power cables, or the like. Optionally, the server 100 is not limited to configurations having the same directional alignment as described and shown in the examples herein, but can also be arranged in other exemplary configurations.

Where the server 100 is mounted within the server rack 200 as show in FIG. 2, the component module bay 108 can be accessible along the installation direction of the component module 102. In one example, the cover opening 110 (FIG. 1) can be located on the front or back of the server so the component module 102 can be installed into the component module bay 108 from the front or the back of the server 100. The component module 102 can be installed when the cover 106 is attached to the server 100. As a result, the component 116 can be installed or removed during the operation of the server 100 (e.g., hot swapped) by installing or removing the component module 102 through the cover opening 110 and into the component module bay 108. Accordingly, the server 100 can be statically mounted within the server rack 200. The reduced need for slidable server mounts can correspondingly reduce the cost and complexity of the server rack 200.

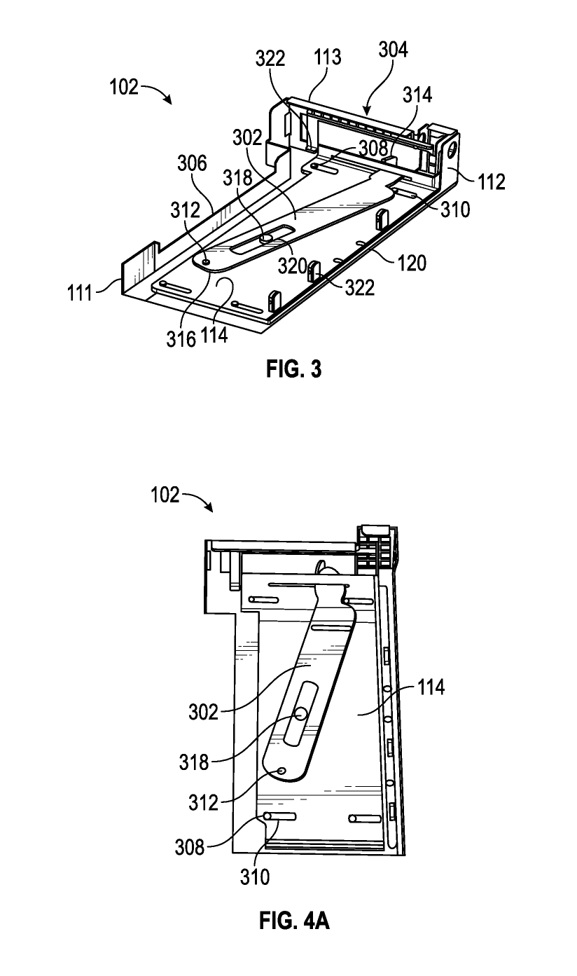

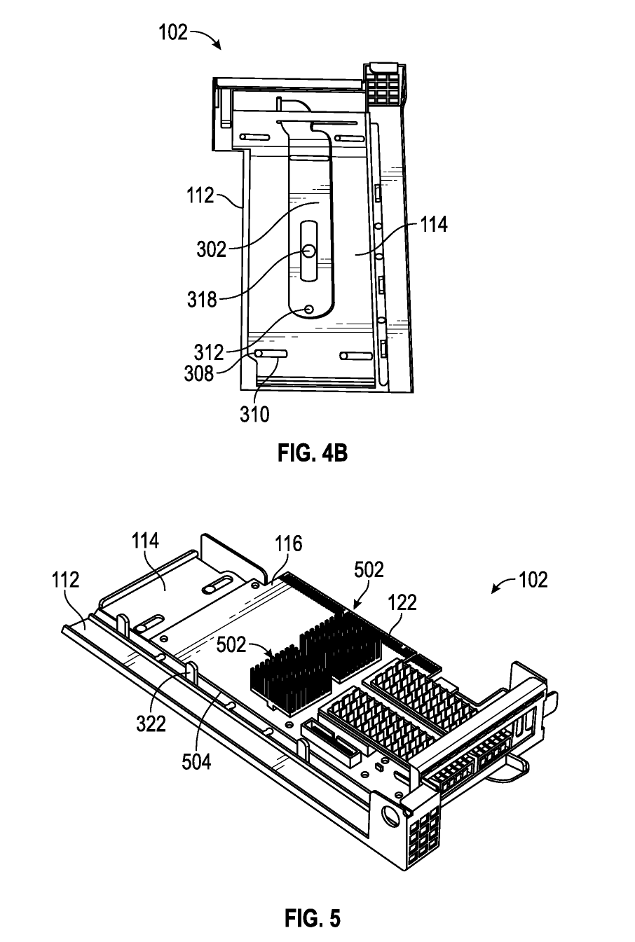

FIG. 3 is a perspective view of the component module 102 according to an example. As previously described herein, the component module 102 can include a frame 112 and a component platform 114 movably coupled to the frame 112. A component actuator arm 302 can be coupled to both the component platform 114 and the frame 112. For instance, the component actuator arm 302 can be coupled to the component platform by a rotatable joint 318. A hinge 312 can couple the component actuator arm 302 to the frame 112. The component platform 114 can be movable from the decoupled position to the interfaced position based on the movement of the component actuator arm 302 as shown in FIGS. 4A and 4B and described further herein.

The frame 112 can include the internally facing end 111 and the externally facing end 113, as previously described herein. The frame 112 can provide structural support for the component module 102 and provide a coupling interface for the installation of the component module 102 within the server 100. In one example, the frame 112 can include a rail 120 (as previously described herein) or other coupling interface for engaging with the chassis 104 of the server 100. The frame 112 can be constructed from a material including, but not limited to, aluminum, steel, polymer, or the like. For instance, the frame 112 can be constructed from sheet metal, cast, molded from a polymer, or the like. As shown in the example of FIG. 3, the frame 112 can include a faceplate 304 located on the externally facing end 113. The frame 112 can include one or more flanges 306 along the length or width of the frame 112 to increase the rigidity of the frame 112. In one example, the frame 112 can be configured to fasten to the server 100 as previously described. For instance, the frame 112 can include an aperture for a fastener, such as a screw, to be inserted therethrough to fasten the component module 102 to the server 100, such as within the component module bay 108 of the server 100. The fastener can include, but is not limited to, a screw, clip, snap-fit, latch, or the like.

The component platform 114 can be movably coupled to the frame 112. In one example, the component platform 114 can be movable from a decoupled position to an interfaced position along a lateral direction with respect to the installation direction of the component module 102. One or more slidable couplings 308 can attach the component platform 114 to the frame 112. In the example of FIG. 3, the slidable coupling 308 can include a pin having a first end fixably attached to the frame 112. The component platform 114 can include one or more slots 310. The pin can protrude through the slot 310. In one example, the one or more slots 310 can be located apart from one another, such as near the corners or near the periphery of the component platform 114. The component platform 114 can be movably coupled to the frame 112 by swaging (e.g., deforming) a second end of the pin (the end extended through the slot 310) and accordingly retaining the component platform 114 to the frame 112. The one or more slots 310 can limit the direction and travel of the component platform 114. For instance, the slot 310 can be configured to guide the component platform 114 between the decoupled position and the interfaced position. In one or more examples, the slidable coupling 308 can be a fastener including, but not limited to a screw, rivet, bolt, or other fastener configuration. In other examples, the component platform 114 can be movably coupled to the frame 112 with roller bearings, a sheet metal joint, or the like. In one example, the component platform 114 can be configured to support a component 116 (as described further herein and shown in FIG. 5). For instance, the component platform 114 can include one or more component supports 322. The component supports 322 can be integral to the component platform 114 or coupled to the component platform 114. Further examples of the component supports are described below.

As shown in FIG. 3, the component module 102 can include a component actuator arm 302. The component actuator arm 302 can be rotatable from a decoupled configuration to an interfaced configuration. Accordingly, the component platform 114 can be translatable from the decoupled position to the interfaced position based on the rotation of the component actuator arm 302 from the decoupled configuration to the interfaced configuration. In one example, the component actuator arm 302 can be rotatably coupled to the frame 112 with the hinge 312. For instance, the component actuator arm 302 can include a first actuator end 314 and a second actuator end 316. The first actuator end 314 can be disposed from the externally facing end 113 of the frame 112. In one example, the first actuator end 314 can include a user engageable interface configured for a user to rotate the component actuator arm 302 from the decoupled configuration to the interfaced configuration. The hinge 312 can be located remotely from the first actuator end 314, such as between the first actuator end 314 or between a mid-plane of the component actuator arm and the second actuator end 316. The hinge 312 can include, but is not limited to a pin or fastener as described previously with regard to the slidable coupling 308. For instance, a first end of the hinge 312 can be fixably attached to the frame 112. The hinge 312 can be located through an aperture in the component actuator arm 302. A second end of the hinge 312 can retain the component actuator arm 302 to the component module 102. In one example, the second end of the hinge 312 can be swaged to retain the component actuator arm 302 to the frame 112. Accordingly, the component actuator arm 302 can rotate about the hinge 312. In some examples, the component actuator arm 302 can be constructed from a material including, but not limited to, aluminum, steel, polymer, or the like. For instance, the component actuator arm 302 can be constructed from sheet metal, cast, molded from a polymer, or the like.

The rotatable joint 318 can couple the component actuator arm 302 to the component platform 114 as shown in the example of FIG. 3. The rotatable joint 318 can be located between the hinge 312 and the first actuator end 314. In other examples, the rotatable joint 318 can be located between the hinge 312 and the second actuator end 316. The rotatable joint 318 can rotate and/or translate within the component actuator arm 302 or the component platform 114. For instance, the rotatable joint 318 can be coupled within a slot 320 located on the component actuator arm 302 or the component platform 114. The rotatable joint 318 can travel along the length of the slot 320 as the component actuator arm 302 rotates from the decoupled configuration to the interfaced configuration. For instance, the component actuator arm 302 can include a slot 320 extended along a portion of the length of the component actuator arm 302. The rotatable joint 318 can be located within the slot 320. Accordingly, the rotatable joint 318 can translate in a lateral direction with respect to the installation direction of the component module 102 (e.g., perpendicular to the installation direction), and the component platform 114 can translate between the decoupled position and the interfaced position based on the translation of the rotatable joint 318. In one example, the rotatable joint can include, but is not limited to a boss, lug, pin, flange, or the like. The rotatable joint 318 can be coupled to the component platform 114. In one example, the rotatable joint 318 can be integral with the component platform 114. For instance, the rotatable joint 318 can include a flange disposed from the component platform 114, such as in a normal direction to the component platform 114. The rotatable joint 318 can be constructed from sheet metal, a casting, a molded polymer, machined (e.g., from steel, aluminum, or a polymer), or the like. In one example, the rotatable joint can be rotatably coupled to one of the component platform 114, the component actuator arm 302, or both.

FIG. 4A shows an example of the component module 102 where the component platform 114 is located in the decoupled position. In the decoupled position, the component platform 114 is recessed relative to the interfaced position (e.g., FIG. 4B). Correspondingly, the component actuator arm 302 is located in the decoupled configuration. The component actuator arm 302 is rotatable from the decoupled configuration to the interfaced configuration about the hinge 312. In the example of FIG. 4A, the slidable coupling 308 can be located at a first end of the slot 310 and the hinge 312 can be located at a first end of another slot 310. In one example, the hinge 312 can include the slidable coupling 318 or be integral with the slidable coupling. As shown in FIGS. 4A and 4B, the rotatable joint 318 can be located between the hinge 312 and the first end 314 of the component actuator arm 302.

FIG. 4B shows and example of the component module 102 where the component platform 114 is located in the interfaced position. The component actuator arm 302 is rotated from the decoupled configuration to the interfaced configuration and accordingly the component platform 114 has been translated from the decoupled position to the interfaced position with respect to the frame 112. In the interfaced position, the component platform 114 is translated laterally with respect to the installation direction of the component module 102. The slidable coupling 308 can be located in a second end of the slot 310. For instance, the slidable coupling 308 has translated from the first end of the slot 310 to the second end of the slot 310 according to the translation of the component platform 114 from the decoupled position to the interfaced position. The hinge 312 can be located at the second end of the slot 310 where the component platform 114 is located in the interfaced position, for instance, as a result of the component platform 114 translating from the decoupled position to the interfaced position. The location of the rotatable joint 318 can reduce binding between the slidable couplings 308 and the slots 310. For instance, the rotatable joint 318 can be located in a center portion of the component platform 114, such as at a location having a similar distance from each slidable coupling 308. A rotational moment (e.g., torsion) applied to the component platform 114 by the component actuator arm 302, through the rotatable joint 318, can be reduced, for instance, by arranging the position of the rotatable joint 318 with respect to the one or more slidable couplings 308 to substantially balance the rotational moment applied to the component platform 114.

FIG. 5 shows an example of the component 116 coupled to the component platform 114. For instance, the component 116 can be coupled to the component platform 114 by one or more component supports 322. In one example, the component 116 can be coupled directly to the component platform 114. For instance, the component 116 can be coupled to the component platform 114 with adhesive, one or more fasteners, or the like.

The component 116 can be an electronics module including, but not limited to, a PCI Express card, memory module, hard drive, graphics card, expansion card, power supply, or the like. In one example, the component 116 can include a non-standardized shape. For instance, the component 116 can include a printed circuit board assembly having various shapes and sizes. The printed circuit board assembly can include a plurality of electronics components 502 populated on at least a first side of the printed circuit board assembly. The peripheral shape, e.g., peripheral edge 504, of the component 116 can include straight edges, stepped edges, arcuate edges, or other shapes. The component 116 can include a component contact interface 122. The component contact interface 122 can include at least one electrical contact. For instance, the component contact interface 122 can include, but is not limited to, a board or card edge connector, PCI Express connector, plug, socket, terminal, spring-loaded pin, backplane connector, or the like. In the example of FIG. 5, the component contact interface 122 can include an engagement axis oriented laterally from the installation direction of the component module 102.

The component support 322 can be configured to support the component 116. For instance, the component support 322 can be configured to hold the peripheral edge 504 of the component 116. In the example of FIG. 5, the component support 322 can isolate the component 116 from the component platform 114. For instance, the component support 322 can electrically isolate the component 116 from other elements of the component module 102 to mitigate electrical shorting, electrostatic discharge, of the like. In one example, the component support 322 can minimize vibration, collision, heat transfer, or other sources of damage to the component 116.

As shown in FIG. 5, the component support 322 can be disposed from the component platform 114. The component support 322 can include a first portion coupled to the component platform 114. For instance, the first portion can be fastened to the component platform 114 at one or more of a plurality of locations along the component platform 114. In one example, the component support 322 can be rotatably or adjustably fastened to the component platform 114. For instance, the component support 322 can be adjustably configured to hold a variety of shaped and sized components 116, such as rotated to support a plurality of peripheral edges 504 along different orientations. A second portion of the component support 322 can be configured to support the component 116. In one example, the component support 322 can hold the first side and a second, opposing side, of the component 116. For instance, the second portion of the component support 322 can include a groove configured to hold the first and second sides of the component 116 between opposing surfaces of the groove. In one example, the second portion of the component support 322 can be configured to clamp the first and second sides of the component 116. In one example, the component support 322 can be integrated with the component platform 114. For instance, as previously shown in FIG. 3, the component support 322 can include a flange disposed from the component platform 114. The flange can include a tab, slot, hole, or other feature configured to support the component 116.

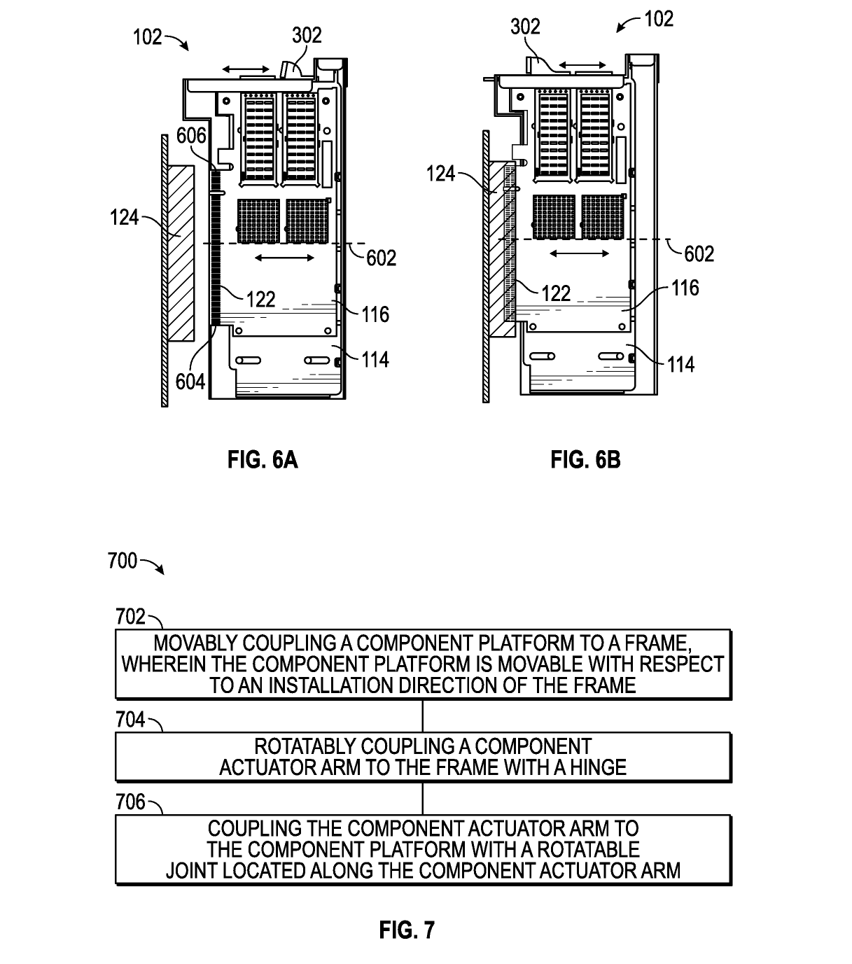

FIG. 6A shows an example of the component 116 located in the decoupled position according to the decoupled configuration of the component actuator arm 302. For instance, the component platform 114 and correspondingly the component 116 are recessed relative to the interfaced position. That is, the component platform 114 and the component 116 are spaced apart from the server contact interface 124 in the decoupled position. As a result, the component 116 (coupled to the component module 102) can be installed within the component module bay 108 with clearance to the server contact interface 124. In other words, the component contact interface 122 and the server contact interface 124 are disengaged where the component platform 114 is located in the decoupled position.

FIG. 6B shows an example of the component 116 located in the interfaced position. For instance, the component actuator arm 302 can be rotated relative to the decoupled configuration to the interfaced configuration, as shown. The component platform 114 can be laterally moved into the interfaced position relative to the installation direction by the component actuator arm 302. Accordingly, the component 116 can moved to the interfaced position where the component contact interface 122 and the server contact interface 124 are engaged. For instance, the component 116 can be in electrical communication with the server components of the server 100 through the engagement of the component contact interface 122 and the server contact interface 124. In one example, the component module 102 can be installed in the server 100 when the server is in operation (e.g., powered on). Accordingly, the component contact interface 122 can be engaged with the server contact interface 124 along a lateral direction to the installation direction of the component module 102 while the server 100 is in operation and the cover 106 is installed.

In one example, the location of the rotatable joint can minimize torsion (i.e., a rotational moment) applied to the component 116 and reduce the amount of force to engage the component contact interface 122 with the server contact interface 124. For instance, the rotatable joint 318 (FIG. 3) can be located on the component platform 114 somewhere along the direction of movement of the component contact interface 122. In one example, the rotatable joint 318 can be located somewhere along an engagement axis 602 of the component contact interface 122. The engagement axis 602 can be located at the center of the component contact interface 122 and extended along the direction of lateral movement of the component platform 114. In one example, the rotatable joint can be at a location corresponding to an area of the component 116 extended along the lateral direction of the component module 102 between a first end 604 and a second end 606 of the component contact interface 122 (where the component 116 is assembled to the component module 102). Locating the rotatable joint 318 near the engagement axis 602 can reduce the rotational moment applied to the component 116 when the component actuator arm 302 is moved between the decoupled configuration and the interfaced configuration. For instance, the rotational moment can be applied to the component 116 by the server contact interface 124 as a result of a reaction force produced by the engagement of the component contact interface 122 and the server contact interface 124 or by force applied to the component actuator arm 302. The amount of force applied to the first actuator end 314 to engage the component contact interface 122 and the server contact interface 124 can be reduced by locating the rotatable joint 318 near the component contact interface 122. For instance, a mechanical advantage is achieved by locating the rotatable joint 318 between the hinge 312 and the first actuator end 314. The mechanical advantage (e.g., leverage) corresponds to the relative distances between the hinge 312, rotatable joint 318, and the first actuator end 314.

FIG. 7 is a block diagram of an exemplary method 700 for making a component module 102, such as the component module 102 previously described in the examples herein and shown for instance in FIGS. 1-6. In describing the method 700, reference is made to one or more components, features, functions, and steps previously described herein. Where convenient, reference is made to the components, features, steps and the like with reference numerals. Reference numerals provided are exemplary and are nonexclusive. For instance, features, components, functions, steps, and the like described in the method 700 include, but are not limited to, the corresponding numbered elements provided herein. Other corresponding features described herein (both numbered and unnumbered) as well as their equivalents are also considered.

At 702, the component platform 114 can be movably coupled to the frame 112. The component platform 114 is movable (e.g., in a lateral direction) with respect to the installation direction of the frame 112. For instance, the component platform 114 can be movably coupled between the decoupled position and the interfaced position. In one example, the component platform 114 can be coupled to the frame 112 as previously described herein and shown in FIGS. 1-6.

At 704, the component actuator arm 302 arm can be rotatably coupled to the frame 112 with the hinge 312, the component actuator arm 302 can include the first actuator end 314 and the second actuator end 316. The component actuator arm 302 can be rotatable about the hinge 312 from the decoupled configuration to the interfaced configuration as shown in FIGS. 4A-B and 6A-B and can be coupled to the frame 112 as previously described herein.

At 706, the component actuator arm 302 can be coupled to the component platform 114 with the rotatable joint 318 located along the component actuator arm 302. The component actuator arm 302 can be configured to laterally move the component platform 114 between the decoupled and the interfaced positions based on the rotation of the component actuator arm 302 around the hinge 312 and correspondingly the translation of the rotatable joint 318 coupled with the component platform 114 as previously described and shown in FIG. 4A-B. In one example, the component actuator arm 302 can be coupled to the component platform 114 with the rotatable joint 318, such as movably coupled between the component actuator arm 302 and the component platform 114. For instance, as previously described, the rotatable joint 318 can be coupled within a slot located on the component actuator arm 302 or the component platform 114. The rotatable joint 318 can travel along the length of the slot as the component actuator arm 302 rotates from the decoupled configuration to the interfaced configuration. Accordingly, the rotatable joint 318 can translate in the lateral direction with respect to the installation direction of the component module 102, and the component platform 114 can translate between the decoupled position and the interfaced position based on the translation of the rotatable joint 318. In one example, the rotatable joint 318 can be coupled to the component actuator arm 302 at a location between the first actuator end 314 and the hinge 312 as previously described and shown in FIGS. 3, 4A, and 4B.

In one example, the component 116 can be coupled to one or more component supports 322. The one or more component supports 322 can be coupled to the component platform 114. As previously described, the component platform 114 can be translatable according to the lateral movement the component platform 114 from the decoupled position to the interfaced position. The component 116 can include the examples previously described. In one example, the one or more component supports 322 can hold the peripheral edge of the component 116. The component supports 322 can be rotatably coupled to the component platform 114 and can be adjustable to support a variety of shaped and sized components 116. In one example, the component 116 can include the component contact interface 122. The component contact interface 122 can be oriented laterally to the installation direction of the frame 112.

An example of an electronic system 800 (e.g., a server 100) using the component module 102 as described in the present disclosure is included to show an example of a higher level device application for the present invention. FIG. 8 is a block diagram of an electronic system 800 incorporating at least one component module 102 and/or method in accordance with at least one embodiment of the invention. Electronic system 800 is merely one example of an electronic system in which embodiments of the present invention can be used. Examples of electronic systems 800 include, but are not limited to servers 100, personal computers, tablet computers, mobile telephones, game devices, MP3 or other digital music players, etc. In this example, electronic system 800 comprises a data processing system that includes a system bus 802 to couple the various components of the system. System bus 802 provides communications links among the various components of the electronic system 800 and can be implemented as a single bus, as a combination of busses, or in any other suitable manner.

An electronic assembly 810 is coupled to system bus 802. The electronic assembly 810 can include any circuit or combination of circuits. In one embodiment, the electronic assembly 810 includes a processor 812 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 810 are a custom circuit, an application-specific integrated circuit (ASIC), or the like, such as, for example, one or more circuits (such as a communications circuit 814) for use in wireless devices like mobile telephones, personal data assistants, portable computers, two-way radios, and similar electronic systems. The IC can perform any other type of function.

The electronic system 800 can also include an external memory 820, which in turn can include one or more memory elements suitable to the particular application, such as a main memory 822 in the form of random access memory (RAM), one or more hard drives 824, and/or one or more drives that handle removable media 826 such as compact disks (CD), flash memory cards, digital video disk (DVD), and the like.

The electronic system 800 can also include a display device 816, one or more speakers 818, and a keyboard and/or controller 830, which can include a mouse, trackball, touch screen, voice-recognition device, or any other device that permits a system user to input information into and receive information from the electronic system 800.

### VARIOUS NOTES & EXAMPLES

Each of these non-limiting examples can stand on its own, or can be combined in various permutations or combinations with one or more of the other examples. To better illustrate the method and apparatuses disclosed herein, a non-limiting list of embodiments is provided here:

Example 1 can include or use a component module including a frame configured for installation in an installation direction; a component platform movably coupled to the frame and movable between interfaced and decoupled positions; a component actuator arm extending between first and second actuator ends, wherein a hinge rotatably couples the component actuator arm to the frame and is remote from the first actuator end, and the component actuator arm is coupled to the component platform at a rotatable joint, wherein the component actuator arm is movable between a decoupled configuration and an interfaced configuration, wherein in the decoupled configuration, the component platform is in the decoupled position and recessed relative to the interfaced position, and in the interfaced configuration the component actuator arm is rotated relative to the decoupled configuration, and the component platform is laterally moved into the interfaced position relative to the installation direction by the component actuator arm.

Example 2 can include the component module of example 1, further comprising one or more component supports coupled to the component platform, the component platform and the one or more component supports configured to couple with a component positioned thereon, wherein a component can be mounted on the component supports.

Example 3 can include the component module of any one of examples 1-2, wherein the one or more component supports can be configured to hold a peripheral edge of the component.

Example 4 can include the component module of any one of examples 1-3, wherein the component can be an expansion card module.

Example 5 can include the component module of any one of examples 1-4, wherein the rotatable joint can be movably coupled with respect to the component actuator arm or the component platform.

Example 6 can include the component module of any one of examples 1-5, wherein the rotatable joint can be located between the first actuator end and the hinge.

Example 7 can include a server including or using a server chassis, the server chassis including a component module bay; a cover; a component module, configured for installation within the component module bay, the component module including: a frame including an insertion direction; a component platform movably coupled to the frame, the component platform including a decoupled position and an interfaced position; a component actuator arm coupled to the component platform and configured to move the component platform laterally with respect to the insertion direction of the frame, from the decoupled position to the interfaced position; and a component coupled to the component platform, the component including a component contact interface.

Example 8 can include the server of example 7, wherein the component module can be installed in the component module bay and removable from the component module bay through a cover opening.

Example 9 can include the server of any one of examples 7-8, wherein the component contact interface can be engageable with a server contact interface along a lateral direction to an installation direction of the frame.

Example 10 can include the server of any one of examples 7-9, wherein in the decoupled position of the component platform, the component contact interface can be disengaged from the server contact interface; and in the interfaced position of the component platform, the component contact interface can be engaged with the server contact interface.

Example 11 can include the server of any one of examples 7-10, wherein the component module can be installable into the component module bay and the component contact interface of the component is engageable with the server contact interface while the server can be operating.

Example 12 can include the server of any one of examples 7-11, wherein the frame includes an externally facing end and an internally facing end at opposing ends of the frame along the installed direction, wherein the internally facing end can be substantially open and configured for receiving airflow across the component.

Example 13 can include the server of any one of examples 7-12, wherein the server can be configured for installation within a rack including a plurality of servers, the server can be configured for a plurality of servers to be arranged along a top, bottom, right, and left sides of the server and a cover opening can be located on a back or front end of the server.

Example 14 can include the server of any one of examples 7-13, wherein the component can be coupled to the component platform with one or more component supports.

Example 15 can include or use a method of making a component module including movably coupling a component platform to a frame, wherein the component platform can be movable with respect to an installation direction of the frame; rotatably coupling a component actuator arm to the frame with a hinge, the component actuator arm including first and second actuator ends, wherein the component actuator arm can be rotatable about the hinge from a decoupled configuration to an interfaced configuration; and coupling the component actuator arm to the component platform with a rotatable joint located along the component actuator arm, wherein the component actuator arm can be configured to laterally move the component platform between the decoupled and the interfaced positions based on the rotation of the component actuator arm around the hinge and correspondingly the translation of the rotatable joint coupled with the component platform.

Example 16 can include the method of example 15, further comprising coupling a component to one or more component supports, wherein the component platform includes the one or more component supports, the component being translatable according to the lateral movement the component platform from the decoupled position to the interfaced position.

Example 17 can include the method of any one of examples 15-16, wherein coupling the component to the one or more component supports includes holding a peripheral edge of the component with the one or more component supports.

Example 18 can include the method of any one of examples 15-17, wherein coupling the component to the one or more component supports includes coupling a component including a component contact interface oriented laterally to the installation direction of the frame.

Example 19 can include the method of any one of examples 15-18, wherein coupling the component actuator arm to the component platform with the rotatable joint includes coupling the component actuator arm to the component platform with the rotatable joint that can be movably coupled between the component actuator arm and the component platform.

Example 20 can include the method of any one of examples 15-19, wherein coupling the component actuator arm to the component platform with the rotatable joint includes coupling the rotatable joint to the component actuator arm between the first actuator end and the hinge.

Example 21 can include or use a component module including a frame configured for installation in an installation direction; a component platform movably coupled to the frame and movably between interfaced and decoupled positions; an actuator assembly coupled with the frame and the component platform, the actuator assembly is configured to move the component platform between the interfaced and decoupled positions laterally relative to the installation direction, the actuator assembly includes a component actuator arm extending between first and second actuator ends, a hinge remote from the first actuator end, the hinge rotatably couples the component actuator arm with the frame, and a rotatable joint coupled between the frame and the component platform.

Example 22 can include a component module including a frame including an insertion direction; a component platform movably coupled to the frame, the component platform including a decoupled configuration and an interfaced configuration; a component actuator arm coupled to the component platform and configured to move the platform laterally with respect to the insertion direction of the frame, from the decoupled configuration to the interfaced configuration; and one or more component supports coupled to the component platform.

Example 23 can include the component module of example 22, wherein a component can be mounted on the component supports.

Example 24 can include the component module of any one of examples 22-23, wherein the one or more component supports can be configured to hold a peripheral edge of the component.

Example 25 can include the component module of any one of examples 22-24, wherein the component can be an expansion card module.

Example 26 can include the component module of any one of examples 22-25, wherein the actuator arm extended between a first and second actuator ends, a hinge rotatably couples the component actuator arm to the frame and can be remote from the first actuator end, and the component actuator arm can be rotatably coupled to the component platform at a joint, wherein the component actuator arm can be movable between a decoupled configuration and an interfaced configuration based on rotation of the component actuator arm around the hinge and translation of the joint coupled with the component platform.

Example 27 can include the component module of any one of examples 22-26, wherein the rotatable joint can be movably coupled with respect to the lever arm or the platform.

Example 28 can include the component module of any one of examples 22-27, wherein the rotatable joint can be located at between the first lever end and the hinge.

Example 29 can include a component module including a frame configured for installation in an installation direction, a component platform movably coupled to the frame and movable between interfaced and decoupled positions, a means for moving the component platform between a decoupled configuration and an interfaced configuration, wherein in the decoupled configuration, the component platform can be in the decoupled position and recessed relative to the interfaced position, and in the interfaced configuration the component actuator arm can be rotated relative to the decoupled configuration, and the component platform can be laterally moved into the interfaced position relative to the installation direction by the component actuator arm.

Example 30 can include the component module of Example 29, further comprising one or more component supports coupled to the component platform, the component platform and the one or more component supports configured to couple with a component positioned thereon, wherein a component can be mounted on the component supports.

Example 31 can include the component module of any one of examples 29-30, wherein the one or more component supports can be configured to hold a peripheral edge of the component.

Example 32 can include the component module of any one of examples 29-31, wherein a component can be coupled to the component platform.

Example 33 can include the component module of any one of examples 29-32, wherein the component includes a component contact interface, the component contact interface can be oriented laterally to the installation direction of the frame.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A component module comprising:
a frame configured for slidable installation with a server along an installation direction, and wherein the frame is configured for slidable removal from the server;
a component platform movably coupled to the frame and movable between interfaced and decoupled positions;
a component actuator arm extending between first and second actuator ends, wherein a hinge rotatably couples the component actuator arm to the frame and is remote from the first actuator end, and the component actuator arm is coupled to the component platform at a rotatable joint, wherein the component actuator arm is movable between a decoupled configuration and an interfaced configuration, wherein
in the decoupled configuration, the component platform is in the decoupled position and recessed relative to the interfaced position, and
in the interfaced configuration the component actuator arm is rotated relative to the decoupled configuration, and the component platform is moved in a lateral direction into the interfaced position relative to the installation direction by the component actuator arm, wherein the lateral direction is different than the installation direction.

2. The component module of claim 1, further comprising one or more component supports coupled to the component platform, the component platform and the one or more component supports configured to couple with a component positioned thereon, wherein a component is mounted on the component supports.

3. The component module of claim 2, wherein the one or more component supports are configured to hold a peripheral edge of the component.

4. The component module of claim 2, wherein the component is an expansion card module.

5. The component module of claim 1, wherein the rotatable joint is movably coupled with respect to the component actuator arm or the component platform.

6. The component module of claim 1, wherein the rotatable joint is located between the first actuator end and the hinge.

7. A server comprising:
a server chassis, the server chassis including a component module bay;
a cover;
a component module, configured for slidable installation with the component module bay, the component module including:
a frame including an installation direction;
a component platform movably coupled to the frame, the component platform including a decoupled position and an interfaced position;
a component actuator arm coupled to the component platform and configured to move the component platform in a lateral direction with respect to the installation direction of the frame, from the decoupled position to the interfaced position, wherein the lateral direction is different than the installation direction; and
a component coupled to the component platform, the component including a component contact interface.

8. The server of claim 7, wherein the component module is installed in the component module bay and removable from the component module bay through a cover opening.

9. The server of claim 7, wherein the component contact interface is engageable with a server contact interface along a lateral direction to the installation direction of the frame.

10. The server of claim 9, wherein:
in the decoupled position of the component platform, the component contact interface is disengaged from the server contact interface; and
in the interfaced position of the component platform, the component contact interface is engaged with the server contact interface.

11. The server of claim 9, wherein the component module is installable into the component module bay and the component contact interface of the component is engageable with the server contact interface while the server is operating.

12. The server of claim 7, wherein the frame includes an externally facing end and an internally facing end at opposing ends of the frame along the installed direction, wherein the internally facing end is substantially open and configured for receiving airflow across the component.

13. The server of claim 7, wherein the server is configured for installation within a rack including a plurality of servers, the server is configured for a plurality of servers to be arranged along a top, bottom, right, and left sides of the server and a cover opening is located on a back or front end of the server.

14. The server of claim 7, wherein the component is coupled to the component platform with one or more component supports.

15. A method of making a component module comprising:
movably coupling a component platform to a frame, wherein the component platform is movable with respect to an installation direction of the frame;
rotatably coupling a component actuator arm to the frame with a hinge, the component actuator arm including first and second actuator ends, wherein the component actuator arm is rotatable about the hinge from a decoupled configuration to an interfaced configuration; and
coupling the component actuator arm to the component platform with a rotatable joint located along the component actuator arm, wherein the component actuator arm is configured to laterally move the component platform between the decoupled and the interfaced positions based on the rotation of the component actuator arm around the hinge and correspondingly the translation of the rotatable joint coupled with the component platform.

16. The method of claim 15, further comprising coupling a component to one or more component supports, wherein the component platform includes the one or more component supports, the component being translatable according to the lateral movement the component platform from the decoupled position to the interfaced position.

17. The method of claim 16, wherein coupling the component to the one or more component supports includes holding a peripheral edge of the component with the one or more component supports.

18. The method of claim 16, wherein coupling the component to the one or more component supports includes coupling a component including a component contact interface oriented laterally to the installation direction of the frame.

19. The method of claim 15, wherein coupling the component actuator arm to the component platform with the rotatable joint includes coupling the component actuator arm to the component platform with the rotatable joint that is movably coupled between the component actuator arm and the component platform.

20. The method of claim 15, wherein coupling the component actuator arm to the component platform with the rotatable joint includes coupling the rotatable joint to the component actuator arm between the first actuator end and the hinge.

21. A component module comprising:
a frame configured for slidable installation with a server along an installation direction, and wherein the frame is configured for slidable removal from the server;
a component platform movably coupled to the frame and movable between interfaced and decoupled positions;
a means for moving the component platform between a decoupled configuration and an interfaced configuration, wherein
in the decoupled configuration, the component platform is in the decoupled position and recessed relative to the interfaced position, and
in the interfaced configuration the component actuator arm is rotated relative to the decoupled configuration, and the component platform is moved in a lateral direction into the interfaced position relative to the installation direction by the component actuator arm, wherein the lateral direction is different than the installation direction.

22. The component module of claim 21, further comprising one or more component supports coupled to the component platform, the component platform and the one or more component supports configured to couple with a component positioned thereon, wherein a component is mounted on the component supports.

23. The component module of claim 22, wherein the one or more component supports are configured to hold a peripheral edge of the component.

24. The component module of claim 21, wherein a component is coupled to the component platform.

25. The component module of claim 24, wherein the component includes a component contact interface, the component contact interface is oriented laterally to the installation direction of the frame.
